(19) United States
(12) Patent Application Publication
(10) Pub. No.: US 2017/0154854 A1
(43) Pub. Date: Jun. 1, 2017

(54) ANTI-EMI SHIELDING PACKAGE AND METHOD OF MAKING SAME

(71) Applicant: SHUNSIN TECHNOLOGY (ZHONG SHAN) LIMITED, Zhongshan (CN)

(72) Inventor: JUN-YI XIAO, Shenzhen (CN)

(21) Appl. No.: 15/181,616

(22) Filed: Jun. 14, 2016

(30) Foreign Application Priority Data
Nov. 30, 2015 (CN) 201510869794.X

(51) Int. Cl. H01L 23/552; H01L 21/78; H01L 21/48; H01L 21/56; H01L 23/498; H01L 23/31

(52) U.S. Cl. CPC H01L 23/552; H01L 23/49838; H01L 23/49827; H01L 23/3114; H01L 21/485; H01L 21/4853; H01L 21/486; H01L 21/565; H01L 21/78

(57) ABSTRACT

An anti-EMI shielding package includes a substrate, a component disposed on the substrate, a glue-injection layer, and a shielding metal layer covering the outer surface of the glue-injection layer. A grounding terminal is positioned on an outer side of the substrate. The substrate defines a first through hole, the component defines a second through hole, and a conductive layer is coated on the inner wall of the first through hole and the second through hole. The shielding metal layer, the conductive layer of the second through hole, the conductive layer of the first through hole, and the grounding terminal are connected and form a conductive loop, the shielding metal layer being grounded. A method of making same provides a simple and reliable shielding package formed with less material and low cost.

### BACKGROUND

1. Technical Field

The subject matter herein generally relates to a field of anti-electromagnetic interference (EMI) shielding.

2. Description of Related Art

Communication devices are required to be small size and high sensitivity for signals. EMI in the small package is an issue to be solved.

Generally, there are several solutions for protecting against external magnetic field on radio frequency (RF) modules: (a) the RF module is mounted on a motherboard, and a metal shielding cover is placed around the RF module; (b) a metal shielding cover is placed on the RF module; (c) conductive material is plated or sprayed onto a surface of the RF module and is grounded; (d) conductive material is plated or sprayed onto a surface of the RF module and is connected to grounding wires outside of the RF module; and (e) conductive material is plated or sprayed onto the top surface of the RF module and is grounded by metal wires, the shielding of the side of the RF module is obtained through the metal wires. However, these solutions still have disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 to FIG. 5 illustrate successive stages in an exemplary process of manufacturing an anti-electromagnetic interference (EMI) shielding package in accordance with an embodiment of the disclosure.

FIG. 6 is a perspective view of an exemplary embodiment of an anti-EMI shielding package in accordance with an embodiment of the disclosure.

### DETAILED DESCRIPTION

The disclosure is illustrated by way of example and not by way of limitation in the figures of the accompanying drawings in which like reference numerals indicate the same or similar elements. It should be noted that references to “an” or “one” embodiment in this disclosure are not necessarily to the same embodiment, and such references can mean “at least one.”

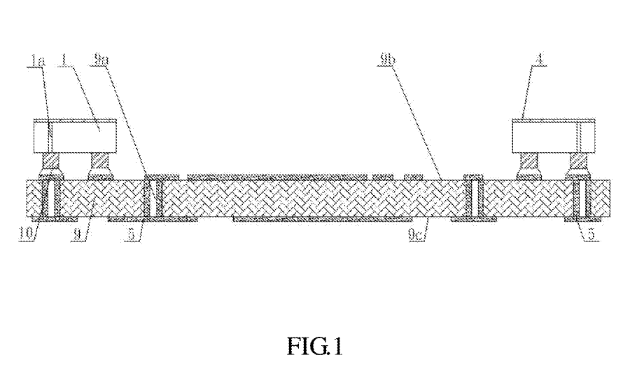

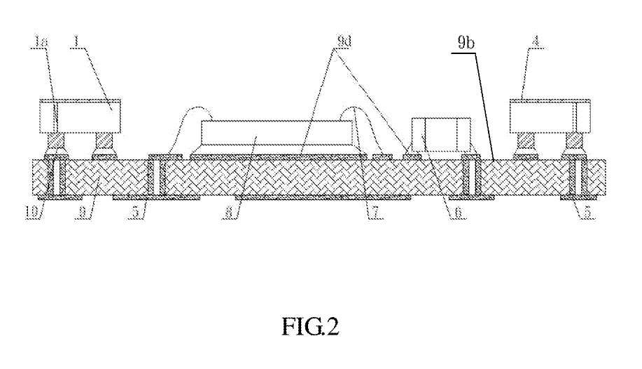

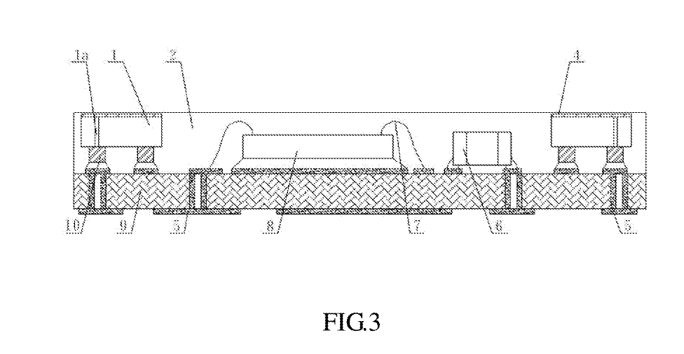

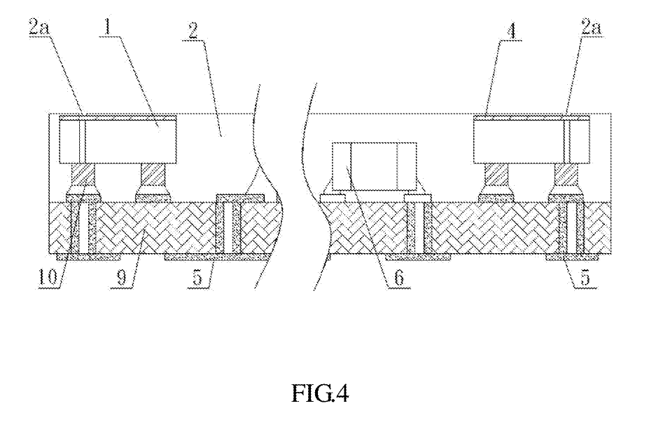

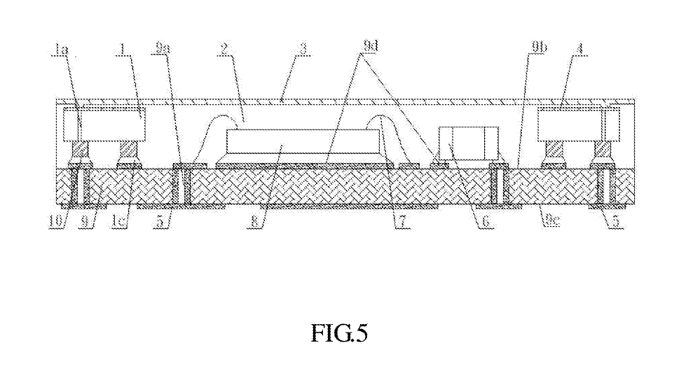

FIG. 1 shows a shielding package. The shielding package comprises a substrate 9, the substrate 9 has a first surface 9b and a second surface 9c parallel to the first surface 9b. Referring to FIG. 2, at least one component is disposed on the substrate 9. The component may be an exposed chip 8 adhesively bonded to the substrate 9, the component may be an exposed chip 8 flipped and soldered in the substrate 9 to form a flip chip 1, the component also can be a passive device 6 assembled on the substrate 9. And the component is disposed on the first surface 9b of the substrate 9. Referring to FIG. 3 and FIG.4, the shielding package further comprises a glue-injection layer 2 covering the component and filling the gap between the component and the substrate 9. Referring to FIG. 5, a shielding metal layer 3 covers the outer surface of the glue-injection layer 2. A grounding terminal 5 is positioned on the outer side of the second surface 9c. The substrate 9 defines a first through hole 9a corresponding to the location of the grounding terminal 5. The first through hole 9a passes from the first surface 9b to the second surface 9c. At least one component defines a second through hole 1a. A conductive layer is coated on the inner wall of the first through hole 9a and the second through hole 1a. The glue-injection layer 2 defines a notch 2a (as shown in FIG. 4). A conductor inside the notch 2a can communicate with the shielding metal layer 3 and the conductive layer of the second through hole 1a. The shielding metal layer 3, the conductive layer of the second through hole 1a, the conductive layer of the first through hole 9a, and the grounding terminal 5 are connected in sequence to form a conductive loop, and the shielding metal layer 3 is grounded.

In the embodiment, the grounding terminal 5 is positioned on the second surface 9c of the substrate 9 to directly connect to ground. In an alternative embodiment, the grounding terminal 5 may be disposed on any part of the substrate 9 which is without a coated layer. The grounding terminal 5 may be directly connected to ground. In an alternative embodiment, the grounding terminal 5 may be connected to a grounded shell of other electrical equipment. The shielding metal layer 3 may be grounded by either method.

Referring to FIG. 5, when the component is an exposed chip 8, the exposed chip 8 is flipped and soldered in the substrate 9 to form a flip chip 1. Specifically, the exposed chip 8 is mounted and connected to the substrate 9 through a plurality of conductive copper columns 10 and flip bonding pins 1c. Thus the conductive layer of the first through hole 9a, the conductive layer of the second through hole 1a, and the flip bonding pin 1c are conductively connected through the conductive copper column 10, and a pathway as a conductive loop is formed by connecting the shielding metal layer 3, the conductor inside the notch 2a (as shown in FIG. 4), the conductive layer of the second through hole 1a, the conductive layer of the first through hole 9a, the conductive copper column 10, the flip bonding pin 1c, and the grounding terminal 5. The shielding metal layer 3 must also be grounded. When the component is an exposed chip 8, the exposed chip 8 may be adhesively bonded to the substrate 9 and electricity connected to the substrate by a bonding wire 7. The component also can be a passive device 6 or surface mounted packaged chip assembled on the substrate.

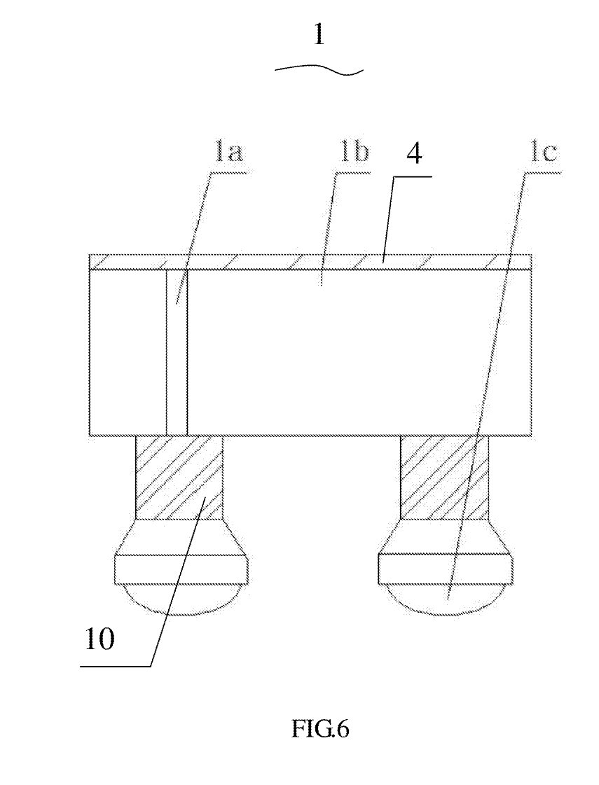

To simplify the structure and processing of the shielding package, the conductor is a part of the shielding metal layer 3 inside the notch 2a. Taking the flip chip 1 as an example, and referring to FIG. 6, the flip chip 1 includes a chip body lb. Conductive copper columns 10 are disposed on one surface of the flip chip 1, bonding pins 1c are positioned on the front end of the conductive copper column 10, and the flip chip 1 is flipped and soldered on the substrate 9 by the bonding pins 1c. There is a chip metal layer 4 on the other surface of the flip chip 1, the chip body 1b defines a second through hole 1a connected to the chip metal layer 4, and conductive layer is coated in the inner wall of the second through hole 1a. The flip chip 1 is mounted on the substrate 9 and packaged by glue-injection layer 2 (as shown in FIG. 5). The glue-injection layer defines a notch 2a connected to the chip metal layer 4, therefore, the shielding metal layer 3 is infilled into the notch 2a at the same time as a shielding metal layer 3 is formed on the surface of the glue-injection layer 2. The shielding metal layer 3 and the chip metal layer 4 of the flip chip 1 are thus electrically connected, and a conductive loop is formed by connecting with the shielding metal layer 3, the chip metal layer 4 of the flip chip 1, the conductive layer of the second through hole la, the conductive copper column 10, the flip bonding pin 1c, the conductive layer of the first through hole 9a, and the grounding terminal 5. The shielding metal layer 3 being grounded protects the flip chip 1 packaged on the substrate 9 from electromagnetic interference. It is understood that other components such as exposed chip, passive device, chip package can also be shielded between the substrate 9 and the shielding metal layer 3.

In the embodiment of the shielding package, the defining of a conductive through hole inside the component and substrate to make the shielding metal layer 3 grounded achieves effective EMI shielding. There is no requirement of peripheral shielding device and peripheral shielding wires, the shielding package not only simplifies the structure, but also decreases its size.

As shown in FIG. 1 to FIG. 6, a method for manufacturing an anti-electromagnetic interference (EMI) shielding package comprises the following steps.

First, a substrate 9 is manufactured, and at least one grounding terminal 5 is positioned on the outer side of the substrate 9. A first through hole is defined in the substrate 9, and the first through hole 9a is created opposite to the grounding terminal 5. A conductive film is coated on the inner wall of the first through hole 9a, and the conductive film is electrically connected to the grounding terminal 5.

At least one component is mounted on the substrate 9 and a second through hole 1a is defined in the substrate 9. A conductive film is coated on the inner wall of the second through hole 1a, and the conductive film of the second through hole 1a is electrically connected to the conductive film of the first through hole 9a.

The component is encapsulated in a glue-injection layer 2, the glue-injection layer 2 infilling the gap between the component and the substrate 9. Thus, all parts are packaged on the substrate 9.

A notch 2a is formed, positioned on the glue-injection layer 2, and the glue-injection layer 2 is connected to the second through hole 1a.

A shielding metal layer 3 is formed on an outer surface of the glue-injection layer 2, the shielding metal layer 3 fills up the notch 2a, and the shielding metal layer 3 is electrically connected to the conductive film of the second through hole 1a. Specifically, the shielding metal layer 3 can be formed by sputtering copper materials on the surface of glue-injection layer. In an alternative embodiment, the shielding metal layer 3 can be made of high-permeability glue and have high conductivity using one of iron, cobalt, nickel, in an alloy with glue.

In order to improve the processing efficiency of manufacturing the substrate 9, the substrate 9 can be divided into multiple substrate units according to predetermined specifications. The grounding terminal 5, the first through hole 9a and the conductive film of the inner wall of the first through hole 9a are formed on the substrate units. In addition, after forming the shielding metal layer 3, the substrate 9 is cut into shielding package units. Advantages are that in the step of forming the shielding metal layer 3, splash plating the entire substrate may greatly save material cost compared to splash plating each of the the substrate units. In addition, there is no metal splash plated on the sidewall of the cut shielding packaging unit, avoiding the issue of short circuits when the shielding packaging is installed on a circuit board.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

1. An anti-electromagnetic interference (EMI) shielding package, comprising:
a substrate;
at least one component disposed on the substrate;
a glue-injection layer encapsulating the component and filling a gap between the component and the substrate;
a shielding metal layer covering the outer surface of the glue-injection layer; and
at least one grounding terminal positioned on an outer side of the substrate, wherein the substrate defines a first through hole corresponding to the grounding terminal, the component defines a second through hole, inner walls of the first through hole and the second through hole are coated with a conductive layer, wherein the shielding metal layer, the conductive layers of the second through hole and the first through hole, and the grounding terminal are connected in sequence to collectively form a conductive loop.

2. The anti-EMI shielding package of claim 1, wherein the substrate comprises a first surface and a second surface parallel to the first surface, the component is disposed on the first surface, the grounding terminal is positioned on the outer side of the second surface, the first through hole is passed from the first surface to the second surface.

3. The anti-EMI shielding package of claim 1, wherein the glue-injection layer defines a notch in communication with the second through hole and the shielding metal layer, and a conductor inside the notch connects the shielding metal layer and the second through hole.

4. The anti-EMI shielding package of claim 3, wherein the conductor is a part of the shielding metal layer inside the notch.

5. The anti-EMI shielding package of claim 1, wherein the component is an exposed chip flipped and welded on the substrate.

6. The anti-EMI shielding package of claim 1, wherein the component is an exposed chip bonded to the substrate and electricity connected to the substrate by a bonding wire.

7. The anti-EMI shielding package of claim 1, wherein the component is a passive device or a chip package, the passive device or the chip package is assembled on the substrate using surface mount technology.

8. A method of manufacturing anti-EMI shielding package, the method comprising:
manufacturing a substrate, at least one grounding terminal positioned on the outer side of the substrate, the substrate defining a first through hole opposite to the corresponding grounding terminal, a conductive film coated on the inner wall of the first through hole and electricity connected to the grounding terminal;
mounting at least one component on the substrate and defining a second through hole, a conductive film coated on the inner wall of the second through hole and electricity connected to the conductive film of the first through hole;
encapsulating the component with a glue-injection layer, wherein the glue-injection layer fills the gap between the component and the substrate;
defining a notch in the glue-injection in communication with the second through hole;
forming a shielding metal layer on an outer surface of the glue-injection layer, wherein the shielding metal layer fills up the notch and is electricity connected to the conductive film of the second through hole.

9. The method of claim 8, wherein the substrate is divided into a plurality of substrate units according to a predetermined specification, the grounding terminal, the first through hole and the conductive film of the inner wall of the first through hole are formed on the substrate unit, and the method further comprises cutting the substrate into shielding package units after the step of forming the shielding metal layer.

10. The method of claim 8, wherein the shielding metal layer is formed on the outer surface of the glue-injection layer by metal splash plating.
